(19) United States
(12) Patent Application Publication
(10) Pub. No.: US 2011/0308936 A1
(43) Pub. Date: Dec. 22, 2011

(54) METHOD FOR MANUFACTURING LANTHANUM BORIDE FILM

(75) Inventors: Yoichi Murakami, Utsunomiya-shi (JP); Naofumi Aoki, Chigasaki-shi (JP)

(73) Assignee: CANON KABUSHIKI KAISHA, Tokyo (JP)

(21) Appl. No.: 13/165,167

(22) Filed: Jun. 21, 2011

(30) Foreign Application Priority Data
Jun. 22, 2010 (JP) 2010-141942

(51) Int. Cl. C23C 14/06; C23C 14/34

(52) U.S. Cl. 204/192.1

(57) ABSTRACT

A method for manufacturing a lanthanum boride film includes, in the state in which a lanthanum boride target having an oxygen content in a range of 0.4 to 1.2 percent by mass and a substrate are arranged to face each other, a step of forming a lanthanum boride film on the substrate by a sputtering technique, and when the mean free path of a sputtering gas molecule in film formation is represented by λ (mm) and the distance between the substrate and the target is represented by L (mm), L/λ is set to 20 or more, and the value obtained by dividing a discharge electrical power by a target area is set in a range of 1 to 5 W/cm².

### BACKGROUND OF THE INVENTION

1. Field of the Invention

The present invention relates to a method for manufacturing a lanthanum boride film using a sputtering technique and an electron-emitting device using a lanthanum boride film.

2. Related Background Art

Japanese Patent Laid-Open No. 2009-183719 has disclosed that by using a polycrystal film of lanthanum boride for an electron-emitting device, a drive voltage and variation of emission current can be reduced.

### SUMMARY OF THE INVENTION

When a lanthanum boride film used as an electron emission material for an image display apparatus is manufactured with good yield, a film having a low work function is required to be reproducibly and uniformly formed. The present inventors found that in film formation by a sputtering technique, the oxygen content in a target has an influence on the reproducibility of the work function value of a deposited lanthanum boride film.

Hence, aspects of the present invention provide a method for manufacturing a lanthanum boride film having a low work function with good reproducibility by a sputtering technique. Aspects of the present invention further provide a method for manufacturing an electron-emitting device having excellent electron emission properties (in particular, the stability in electron emission) with good reproducibility.

Aspects of the present invention provide a method for manufacturing a lanthanum boride film which includes, in the state in which a lanthanum boride target having an oxygen content in a range of 0.4 to 1.2 percent by mass and a substrate are arranged to face each other, a step of forming a lanthanum boride film on the substrate by a sputtering technique, wherein when the mean free path of a sputtering gas molecule in film formation is represented by λ (mm) and the distance between the substrate and the target is represented by L (mm), L/λ is set to 20 or more, and the value obtained by dividing a discharge electrical power by a target area is set in a range of 1 to 5 W/cm².

According to aspects of the present invention, a lanthanum boride film having a low work function can be reproducibly and uniformly manufactured.

Further features of the present invention will become apparent from the following description of exemplary embodiments with reference to the attached drawings.

### BRIEF DESCRIPTION OF THE DRAWINGS

FIG. 1 is a schematic view of a parallel plate type sputtering apparatus.

FIG. 2A is a schematic view showing a sputtering apparatus.

FIG. 2B is a graph showing the relationship between the crystallinity of a lanthanum boride film and a film formation position.

FIG. 3 is a graph showing the relationship between the crystallinity of a lanthanum hexaboride film and a film formation condition (L/λ).

FIGS. 4A to 4C are each a schematic view of an electron-emitting device.

FIGS. 5A to 5F are each a schematic cross-sectional view showing one example of a method for manufacturing an electron-emitting device.

### DESCRIPTION OF THE EMBODIMENTS

Hereinafter, with reference to the drawings, preferable embodiments of the present invention will be described. However, the size, the material, the shape, the relative arrangement thereof, and the like of constituent elements disclosed in the embodiments do not limit the scope of the present invention thereto unless otherwise particularly specified.

### (Sputtering Technique)

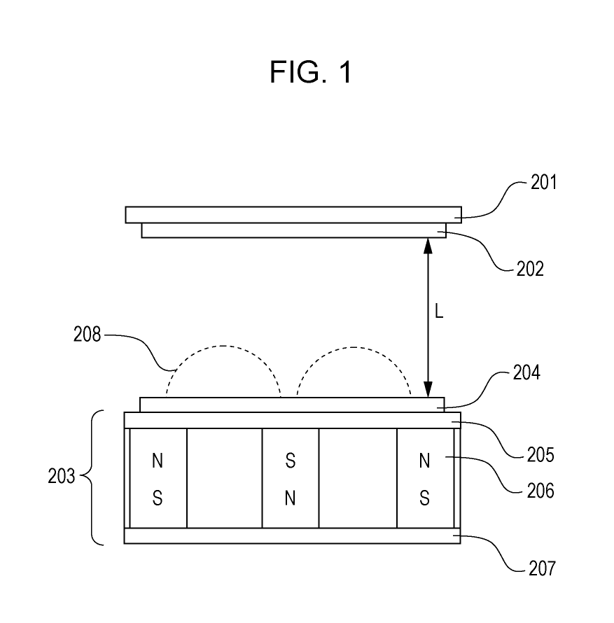

A sputtering apparatus and a sputtering technique will be described with reference to FIG. 1. FIG. 1 is a schematic view showing the inside of a chamber of a parallel plate type sputtering apparatus. The sputtering apparatus includes a substrate holder 201 holding a substrate 202 and a cathode 203 on which a target 204 is provided. The cathode 203 has a backing plate 205, a magnet 206, and a yoke 207. The magnet 206 is formed of a doughnut-shaped outside magnet and an inner magnet arranged at the center of the outside magnet, and by this magnet, a magnetic field as shown by a magnetic field line 208 is formed.

After vacuum evacuation of the inside of the chamber is performed, for example, to 2×10⁻⁴ Pa or less, using a high vacuum evacuation pump, a film is formed by introducing a sputtering gas to maintain a predetermined pressure and applying an electrical power to the cathode 203. Although an argon (Ar) gas, a krypton (Kr) gas, a xenon (Xe) gas, or the like may be used as a sputtering gas, in particular, an argon gas may be used in view of a manufacturing cost. As a sputtering power source, a DC power source or an RF power source having an industrial power supply frequency of 13.56 MHz or the like may be used.

In aspects of the present invention, a value (L/λ) obtained by dividing a distance L (mm) between the substrate 202 and the target 204 by a mean free path λ (mm) of a sputtering gas molecule introduced into the chamber is maintained at 20 or more.

The mean free path λ of gas indicates the average distance in which a gas molecule can travel without scattering (collision) and can be obtained by the following formula.

λ=(k×T)/(√2×π×σ²×P)

In the above formula, k indicates Boltzmann's constant, T indicates the temperature, sigma indicates the diameter of a molecule, and P indicates the pressure.

Since an L/λ of 20 or more is maintained, a film having excellent crystallinity and electron emission properties (in particular, stability of electron emission) can be manufactured. Hereinafter, the reason for this will be described.

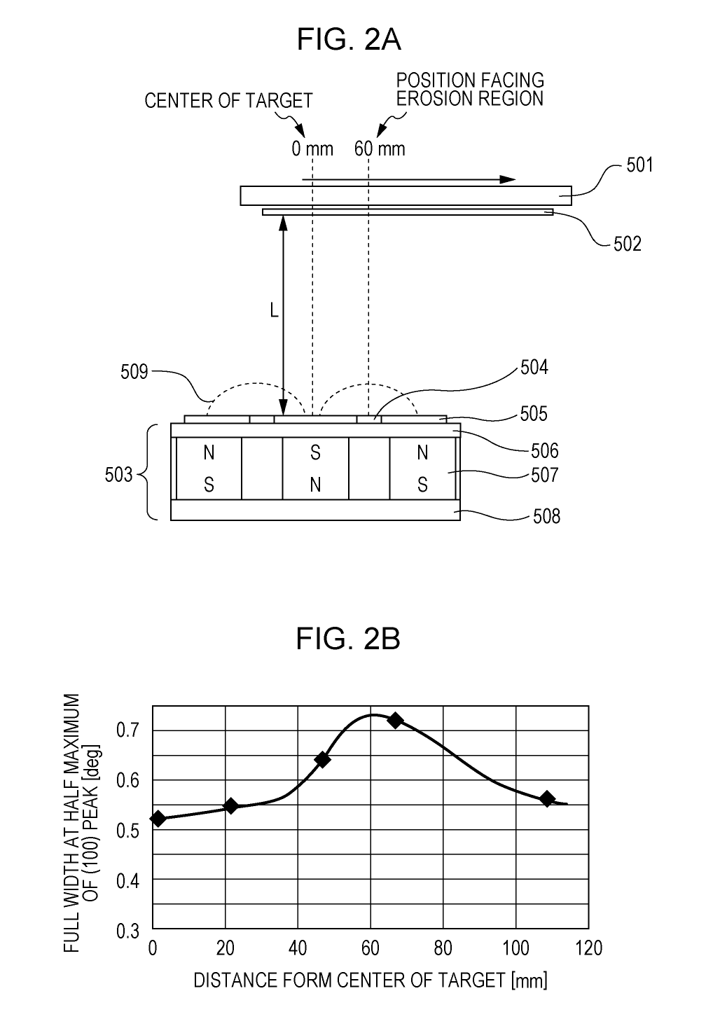

Although a lanthanum boride film formed by a sputtering technique according to aspects of the present invention is a polycrystal film, the film quality (crystallinity) thereof varies depending on a relative position with respect to an erosion region of a target. This variation will be described with reference to FIGS. 2A and 2B. FIG. 2A is a schematic view showing a layout of a parallel plate type sputtering apparatus similar to that shown in FIG. 1. Reference numeral 501 indicates a substrate holder, reference numeral 502 indicates a substrate, and reference numeral 503 indicates a cathode. The cathode 503 is formed of a target 505, a backing plate 506, a magnet 507, and a yoke 508. A magnetic field as shown by a magnetic field line 509 is generated by the magnet 507, and reference numeral 504 indicates an erosion region. By using the apparatus as described above, a circular lanthanum hexaboride plate having a diameter of 8 inches was used as a target, a silicon wafer substrate was used as the substrate 502, the substrate temperature was maintained at room temperature, and an Ar gas was supplied to obtain a total pressure of 1.5 Pa, thereby forming a lanthanum boride film having a thickness of 50 nm on the silicon waver substrate. An RF power supplied to the target was 500 W, and the distance between the target and the substrate was 90 mm. When the lanthanum boride film formed as described above was analyzed using an X-ray diffraction method, the relationship between the full width at half maximum (hereinafter, referred to as “FWHM”) of the diffraction peak of the (100) plane and the substrate position was as shown in FIG. 2B. The crystalline size of crystal is increased as the FWHM is decreased, and hence a small FWHM indicates good crystallinity. The substrate position is represented by the distance from the center of the target shown in FIG. 2A. As shown in FIG. 2B, at a position facing the erosion region, the FWHM is increased, and on the other hand, at a position apart from the position facing the erosion region, the FWHM is decreased.

That is, it was found that the film quality varies and that at the position facing the erosion region, the crystallinity of a lanthanum boride film is degraded. Through further research carried out by the present inventors, it was found that even if the plasma density distribution is changed by changing the magnetic field of a magnet, the crystallinity at the portion facing the erosion region is always degraded. That is, it was found that the film quality has a strong relationship with the erosion position as compared to that with the plasma density distribution. Hereafter, the region (or the position) facing the erosion region is called an erosion facing region (or position). In addition, a region other than the erosion region is called a non-erosion region, and a region (or a position) facing the non-erosion region is called a non-erosion facing region (or position).

The reason the crystallinity of a film at an erosion-facing location is degraded when a lanthanum boride target is used has not been clearly understood; however, through research carried out by the present inventors, it was found that in sputtering using a lanthanum boride target, the film quality at least has position dependence. On the other hand, when an electron-emitting device is used as an electron source of an image display apparatus, it may be the case that a lanthanum boride film is formed as uniform as possible on a large-size substrate. Hence, in order to reduce the position dependence of the film quality, a so-called passage film formation is performed in which film formation is performed while a substrate and a target are relatively moved. In the passage film formation, a portion on the substrate on which a film is to be formed (electron-emitting device) passes through both an erosion facing region and a non-erosion facing region. In this case, when the film quality of a film deposited in the erosion facing region considerably varies from that of a film deposited in the non-erosion facing region, it has been difficult to uniformly form a lanthanum boride film having good crystallinity in which the (100) plane is oriented.

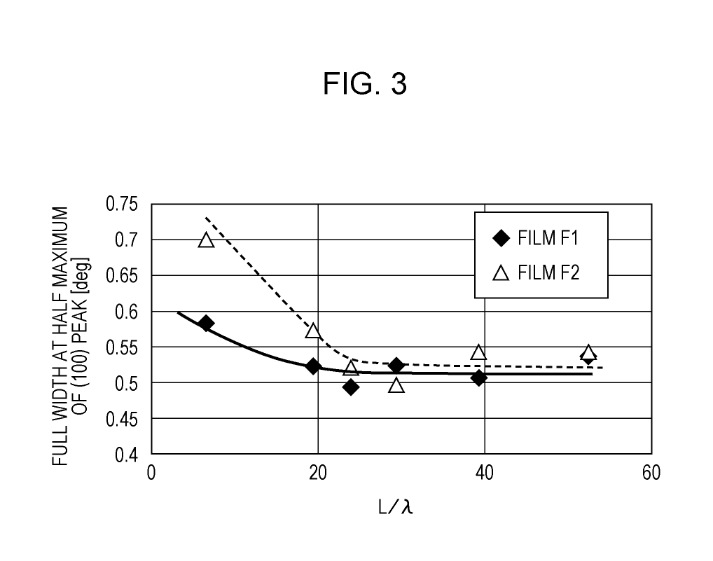

Accordingly, the results obtained through the research on the relationship between the film crystallinity and L/λ in the film formation are shown in FIG. 3. However, in order to compare the crystallinity of a film of the erosion facing region and that of a film of the non-erosion facing region, instead of using the passage film formation, the film formation was performed while the substrate was not moved. In addition, the film formation was performed at an arbitrary Ar-gas pressure in a range of 0.5 to 4.0 Pa (that is, the mean free path λ of an Ar molecule was in a range of 1.7 to 13.7 mm) and at an arbitrary distance L (mm) between the substrate and the target in a range of 90 to 180 mm. The value obtained by dividing the discharge electrical power of an RF power source by the target area was set to approximately 1.5 W/cm².

A film F1 having a thickness of 50 nm deposited in the non-erosion facing region (region facing the center of the target) and a film F2 having a thickness of 50 nm deposited in the erosion facing region were each analyzed by an X-ray diffraction method, and the FWHM of the diffraction peak of the (100) plane of lanthanum hexaboride (hereinafter, simply referred to as “(100) peak” in some cases) was obtained. FIG. 3 shows the relationship between the film formation condition (L/λ) and the FWHM of the (100) peak. As shown in FIG. 3, it is found that when L/λ is small, the FWHM of the (100) peak is large, that is, the film crystallinity is degraded. In addition, the difference in crystallinity between the film F1 and the film F2 is also increased. Furthermore, it is found that as L/λ is increased, the crystallinity is improved, and the difference in crystallinity between the film F1 and the film F2 is decreased.

As described above, when a lanthanum hexaboride film is used as an electron emission material of an electron-emitting device, a film having good crystallinity may be used, for example, of the stability of electron emission. In addition, in order to decrease the difference in electron emission properties of each electron-emitting device (in-plane variation of the electron emission properties), it may be the case that a lanthanum boride film is formed uniformly over the entire substrate.

However, when the crystallinity of one of the films formed in the non-erosion facing region and in the erosion facing region is low, in the film formed by passage film formation, a component having low crystallinity is to be contained. In the case described above, a film having good crystallinity may not be obtained. In addition, when the crystallinities of the two films are different from each other, the electron emission properties of a film formed by passage film formation also become unstable. In addition, also in the case other than the passage film formation, of course, the uniformity of the film quality will be degraded.

Hence, conditions in which the variation of the film quality in a film formation region is reduced and in which a film having good quality can be formed in a wide region are required. In particular, conditions in which the in-plane variation of the FWHM of the (100) peak is less than ±5% or less and in which the FWHM of the (100) peak is 0.6° or less may be provided. From the experimental results shown in FIG. 3, it is found that when the value of L/λ is 20 or more, the conditions described above can be satisfied.

The reason the film quality (crystallinity) can be improved when L/λ is maintained at 20 or more has not been clearly understood. However, one of the reasons for this may be as follows. When L/λ is increased, particles with high energy which jump out from the erosion region in a direction perpendicular thereto are sufficiently scattered, and as a result, a film at the erosion-facing position is suppressed from being damaged.

In addition, in the sputtering technique according aspects of the present invention, although the pressure of a sputtering gas and the distance between a substrate and a target have significant influences on the crystallinity of a lanthanum boride film, the influence of the discharge electrical power on the film crystallinity is not significant. However, the discharge electrical power of a power supply may be set so that the value obtained by dividing the discharge electrical power by a target area is in a range of 1 to 5 W/cm². The reason for this is that when the value is less than 1 W/cm², the energy of sputtered atoms is low, and hence a film having a low work function cannot be easily formed. In addition, the reason for this is that when the value is more than 5 W/cm², a load applied to the target is high, and the target may be damaged in some cases. In addition, when the value is in a range of 1 to 5 W/cm², the relationship between L/λ and the film quality shows the tendency approximately equivalent to that shown in FIG. 3.

In addition, according to aspects of the present invention, the oxygen content of the target 204 arranged to face the substrate 202 is controlled in a range of 0.4 to 1.2 percent by mass.

The relationships between the oxygen content in the target and the reproducibility of the film are shown in Table 1, the relationships each being obtained when the L/λ and the discharge electrical power of a power supply are set to satisfy the conditions described above. When the oxygen content in the target was 0.4 to 1.2 percent by mass, the probability of obtaining a film having a work function of 3.5 eV or less was 80% or more. Even when the oxygen content was 0.8 percent by mass, the probability of obtaining a film having a work function of 3.5 eV or less was 80% or more. On the other hand, when the oxygen content was less than 0.4 percent by mass, and when the oxygen content was more than 1.2 percent by mass, the probability of obtaining a film having a work function of 3.5 eV or less was remarkably low.

TABLE 1

| | | | | | |
|---|---|---|---|---|---|
| Oxygen Content (percent by mass) | 0.2 | 0.4 | 0.8 | 1.2 | 1.8 |
| Reproducibility (%) | 20 | 80 | 80 | 100 | 20 |

In a sputtering technique, an oxygen atom in a target is easily changed into an oxygen negative ion when sputtered, and this oxygen negative ion is charged in negative. Hence, the oxygen negative ion is accelerated in a substrate direction by the electric field of a plasma sheath portion in the vicinity of the target and collides with the film deposited on the substrate. The reason the reproducibility is decreased when the oxygen content is more than 1.2 percent by mass is believed that since the amount of negative ions is large, the arrangement of atoms is destroyed, defects or the like are generated, and as a result, a film having a low work function cannot be formed with good reproducibility. In addition, the reason the reproducibility is low when the oxygen content is less than 0.4 percent by mass has not been clearly understood. However, probably when the amount of negative ions is small, migration of atoms cannot be promoted, and as a result, atoms are suppressed from being aligned. It has been estimated that by the reason described above, a film having a low work function cannot be formed with good reproducibility.

In the sputtering technique according to aspects of the present invention described above, the amount of negative ions emitted from a target can be controlled by the target 204 in which the oxygen concentration is controlled. When the amount of negative ions is controlled, damage done to the film can be prevented, and a lanthanum boride film having a high uniformity and a low work function can be formed with goo reproducibility.

In this embodiment, the film formation is may be performed while the substrate is heated or maintained hot. Although depending on the film formation conditions, the temperature of the substrate may be maintained at 300° C. or more.

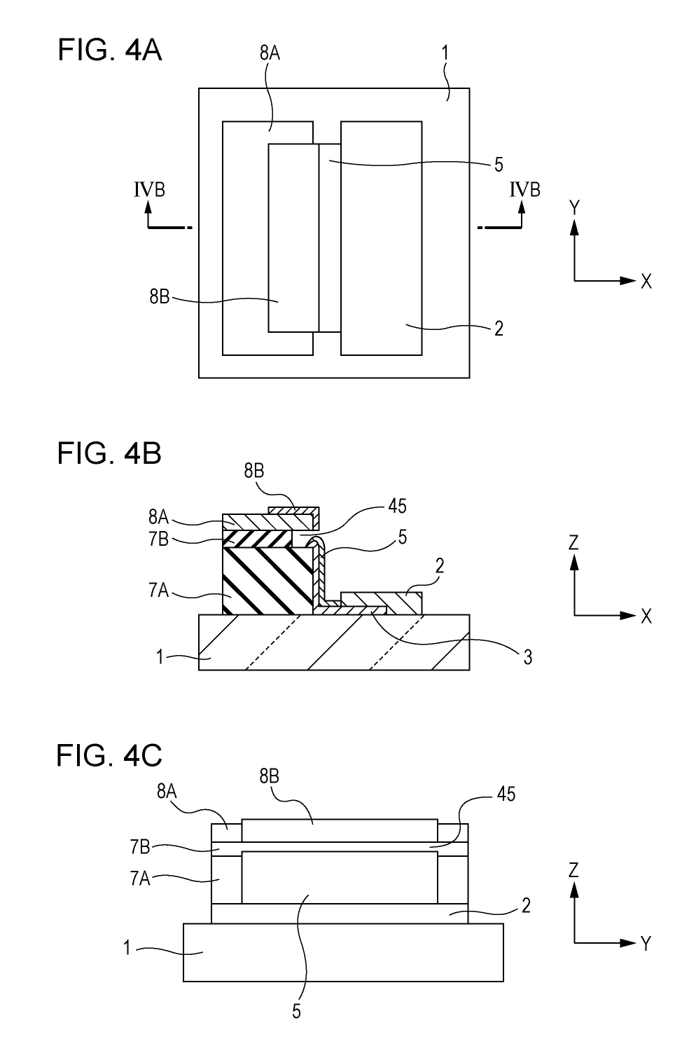

Next, a method for manufacturing a field emission type electron-emitting device including the lanthanum boride film formed in this embodiment will be described with reference to FIGS. 4A, 4B, and 4C. FIG. 4A is a schematic plan view of an electron-emitting device when viewed in a Z direction, and FIG. 4B is a schematic cross-sectional view (Z-X plane) taken along the line IVB-IVB in FIG. 4A. FIG. 4C is a schematic view of the electron-emitting device shown FIG. 4A when viewed in an X direction.

In this electron-emitting device, a gate electrode 8A is provided on a substrate 1 with a first insulating layer 7A and a second insulating layer 7B provided therebetween. In addition, a cathode 2 is provided on the substrate 1, and an electron emission structure (conductive film) 3 connected to the cathode 2 is extended along a side wall of the first insulating layer 7A in a direction apart from the substrate 1. The width of the second insulating layer 7B in the X direction is smaller than that of the first insulating layer 7A, and a recess portion 45 is provided between the first insulating layer 7A and the gate electrode 8A. In addition, as shown in FIG. 4B, the electron emission structure 3 described above protrudes in the Z direction from the upper surface of the first insulating layer 7A. That is, the electron emission structure 3 has a protrusion portion protruding from the upper surface of the first insulating layer 7A toward the gate electrode 8A. In addition, the electron emission structure 3 partially enters the recess portion 45. As a result, it can be said that the electron emission structure 3 has a protrusion portion provided on the surface of the insulating layer 7A located inside the recess portion 45. Electrons are mainly emitted from this protrusion portion.

In addition, FIG. 4B shows one example in which the gate electrode 8A is partially covered with a conductive film 8B formed of the same material as that of the electron emission structure 3. Although this conductive film 8B may be omitted, in order to form a stable electric field, this conductive film 8B may be provided. As a result, in the example shown in FIG. 4B, a gate electrode is formed from the members indicated by 8A and 8B.

The electron emission structure 3 is covered with a lanthanum boride film (such as a lanthanum hexaboride film) 5. This lanthanum boride film 5 is formed by the sputtering technique described above. In the example shown in FIG. 4B, although the whole electron emission structure 3 is covered with the lanthanum boride film 5, the surface of the protrusion portion of the electron emission structure 3 may be at least covered with the lanthanum boride film 5.

As the lanthanum boride film 5, a polycrystal film of lanthanum boride may be more preferable than a single crystal film of lanthanum boride. Compared to a single crystal film, since a polycrystal film is easily formed, the electron emission structure 3 can be covered therewith along a complicated and minute irregular surface as that of the electron emission structure 3, and the internal stress can also be reduced, so that the stability thereof can be obtained. Although the work function of a single crystal film is lower than that of a polycrystal film, when the film thickness and/or the crystalline size thereof are controlled, a work function lower than 3.0 eV which is close to that of a single crystal film can be obtained even by a polycrystal film.

As measurement of the work function of the film obtained by the sputtering technique described above, for example, there may be mentioned a photoelectron spectroscopic method, such as vacuum UPS, a Kelvin method, and a method for deriving the work function from the relationship between an electric field and a current by measuring a field emission current in a vacuum. In addition, the methods mentioned above may be used in combination.

Alternatively, the surface of a sharp protrusion portion of a conductive needle (such as a needle made of tungsten) is covered with a material having a known work function, such as Mo, to have a thickness of approximately 20 nm, and an electric field is applied thereto in a vacuum, so that the electron emission properties are measured. In addition, after a field enhancement factor determined by the shape of the protrusion portion which is a tip of the needle is obtained in advance from the electron emission properties, the protrusion portion is covered with a lanthanum boride film, and the work function can also be calculated.

### EXAMPLES

Hereinafter, more concrete examples will be described.

### Example 1

First, 8 inch-diameter circular lanthanum hexaboride targets having oxygen contents A to E shown in Table 2 were prepared, and a tungsten-made needle (hereinafter, simply referred to a “single needle”) for evaluation of the work function was placed to face each of the targets. The lanthanum hexaboride targets used in this example were each formed in a hot press furnace by pressing and heating a lanthanum hexaboride powder received in a mold. At this stage, the oxygen concentration contained in a gas atmosphere in firing was changed, so that a target having a predetermined oxygen content was obtained. In addition, the oxygen content in the target was identified by a gas analysis. The degree of vacuum in high vacuum evacuation was set to 2×10⁻⁴ Pa, and the value obtained by dividing the discharge electrical power of an RF power source by the target area was set to 3.1 W/cm². In addition, an argon gas (Ar) was used as a sputtering gas, and the pressure thereof was set to 1.5 Pa. The distance L between the single needle and the target 204 was set to 180 mm. That is, L/λ was 39. In addition, a lanthanum boride film having a thickness of 20 nm was formed on the single needle.

TABLE 2

| | Condition | Condition | Condition | Condition | Condition |
|---|---|---|---|---|---|
| | A | B | C | D | E |
| Oxygen | 0.2 | 0.4 | 0.8 | 1.2 | 1.8 |
| Content | | | | | |
| in Target | | | | | |
| (percent by | | | | | |
| mass) | | | | | |
| Repro- | 20 | 80 | 80 | 100 | 20 |
| ducibility | | | | | |
| (%) | | | | | |

Ten single needles each covered with the film formed by using one of the targets A to E having different oxygen contents were formed, and the work function of each film thus obtained was evaluated. The reproducibility (probability in which the work function is 3.5 eV or less) is shown in Table 1. The film formation under one of conditions B, C, and D was performed at a reproducibility of 80% or more, and on the other hand, the reproducibility under each of conditions A and E was 20%. That is, under the conditions B, C, and D, a lanthanum hexaboride film having a low work function was formed with good reproducibility.

In addition, when a polycrystal film of lanthanum boride was formed in a manner similar to that of Example 1 except that L/λ in Example 1 was changed to 19.5 as Comparative Example 1, the uniformity of the film quality was degraded as compared to that of the film formed in Example 1. In the film formed in Example 1, although the in-plane variation of the FWHM of the (100) peak was less than 5%, when L/λ was 19.5, the in-plane variation of the FWHM of the (100) peak was greatly higher than 5%.

### Example 2

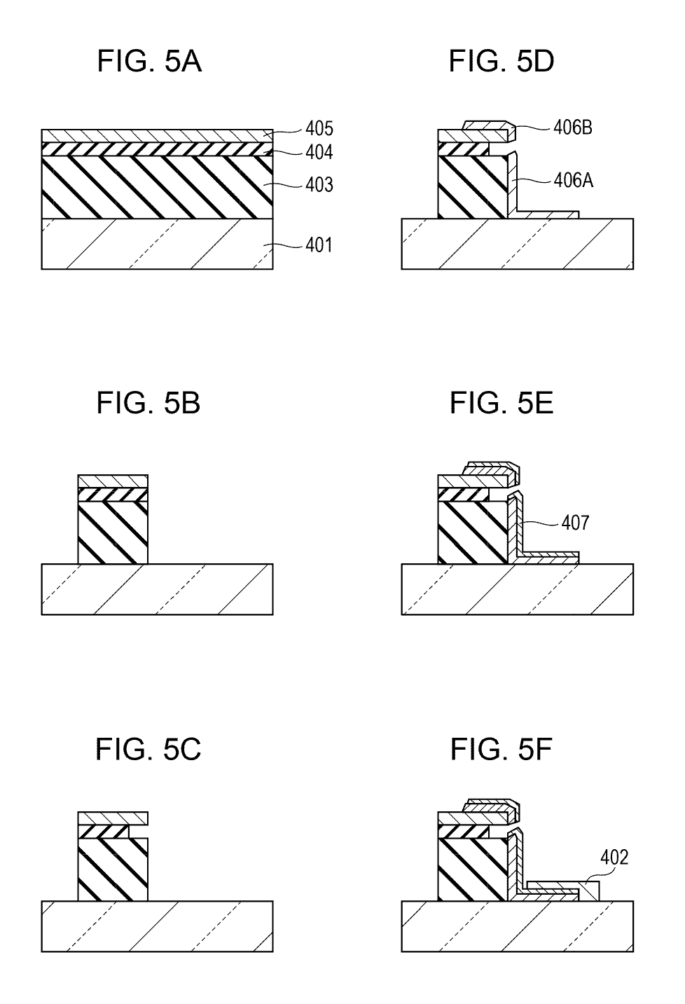

With reference to FIGS. 5A to 5F, a method for manufacturing an electron-emitting device according to Example 2 will be described. FIGS. 5A to 5F are schematic views sequentially showing steps of manufacturing an electron-emitting device.

A substrate 401 is a substrate mechanically supporting a device. In this example, PD200, trade name manufactured by Asahi Glass Co., Ltd., which was a low sodium glass developed for plasma displays, was used as the substrate 401.

First, as shown in FIG. 5A, insulating layers 403 and 404 and a conductive layer 405 were laminated on the substrate 401. The insulating layers 403 and 404 were insulating films each formed of a material having excellent workability. In Example 2, the insulating layer 403 of silicon nitride (SiₓN_{y}) having a thickness of 500 nm and the insulating layer 404 of silicon oxide (SiO₂) having a thickness of 30 nm were formed by a sputtering technique. In addition, the conductive layer 405 of tantalum nitride (TaN) having a thickness of 30 nm was formed by a sputtering technique.

Next, after a resist pattern was formed on the conductive layer 405 by a photolithographic technique, the conductive layer 405, the insulating layer 404, and the insulating layer 403 were processed in this order using a dry etching technique (see FIG. 5B). In this step, a CF₄-based gas was used as a process gas. Reactive Ion Etching (RIE) was performed using this gas, and as a result, the angle of a side surface (inclined surface) of the insulating layer 403 was approximately 80° with respect to the substrate horizontal plane.

After the resist was removed, by using a mixed solution called buffered fluoric acid (BHF) containing ammonium fluoride and fluoric acid, the insulating layer 404 was etched to form a recess portion (see FIG. 5C).

As shown in FIG. 5D, molybdenum (Mo) was adhered on the side surface and the upper surface (inside surface of the recess portion) of the insulating layer 403, so that an electron emission structure (conductive film) 406A was formed. In this step, a molybdenum layer 406B was also adhered on the conductive layer 405 (gate electrode). In this example, an EB vacuum deposition method was used as a film-forming method.

Next, as shown in FIG. 5E, a lanthanum hexaboride film 407 was formed on the electron emission structure 406A. The lanthanum hexaboride film 407 was formed by a method similar to that of Example 1. That is, in sputtering of lanthanum hexaboride, the value obtained by dividing the discharge electrical power of an RF power source by the target area was set to 3.1 W/cm², the pressure P of an Ar gas was set to 1.5 Pa, and the distance between the substrate and the target was set to 180 mm, that is, L/λ was set to 39. In addition, the substrate on which the structure shown in FIG. 5D was formed was placed to face the lanthanum hexaboride target, and the lanthanum hexaboride film 407 was formed by passage film formation.

Next, as shown in FIG. 5F, a cathode 402 was formed by a sputtering technique. Copper (Cu) was used for the cathode 402. The thickness thereof was 500 nm.

The electron-emitting device thus formed was placed in a vacuum device, and the inside thereof was evacuated to 10⁻⁸ Pa. In addition, a pulsed voltage of a rectangular waveform having a pulse width of 1 ms and a frequency of 60 Hz was repeatedly applied between the cathode 402 and the gate electrode 405 so that the electrical potential of the gate electrode 405 was higher than that of the cathode 402. Subsequently, a gate current flowing through the gate electrode 405 was monitored. In addition, at the same time, an anode was provided at a position 5 mm above the substrate 401, and a current (anode current) flowing into the anode was also monitored, so that the variation of the anode emission current was obtained. In order to obtain the variation (fluctuation) of the emission current (anode current), a sequence of measuring the average emission current in response to 32 successive pulse voltages each having a rectangular waveform was performed at intervals of 2 seconds, and the deviation and the average value per 30 minutes were obtained. In addition, (the standard deviation/the average value)×100(%) of the obtained data was calculated. In addition, for comparison purposes, an electron-emitting device in which a lanthanum hexaboride film was formed by a method similar to that of Comparative Example 1 was experimentally formed, and the same measurement as that described above was performed. As a result, compared to the electron-emitting device of the comparative example, the average current variation value of the electron-emitting device of this example was 0.8 times, and good electron emission with little variation in luminance could be performed for a long period of time. In addition, the uniformity of the film quality of the electron-emitting device of this example was superior to that of the comparative example.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-141942 filed Jun. 22, 2010, which is hereby incorporated by reference herein in its entirety.

What is claimed is:

1. A method for manufacturing a lanthanum boride film, comprising, in the state in which a lanthanum boride target having an oxygen content in a range of 0.4 to 1.2 percent by mass and a substrate are arranged to face each other:
forming a lanthanum boride film on the substrate by a sputtering technique,
wherein when the mean free path of a sputtering gas molecule in film formation is represented by λ (mm) and the distance between the substrate and the target is represented by L (mm), L/λ is set to 20 or more, and the value obtained by dividing a discharge electrical power by a target area is set in a range of 1 to 5 W/cm².

2. The method for manufacturing a lanthanum boride film according to claim 1, wherein the sputtering gas is an argon gas.

3. A method for manufacturing an electron-emitting device including a lanthanum boride film, wherein the lanthanum boride film is manufactured by the manufacturing method according to claim 1.
